(19) United States
(12) Patent Application Publication
(10) Pub. No.: US 2026/0282680 A1
(43) Pub. Date: Sep. 17, 2026

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Yi HE, Beijing (CN); Xiangdan DONG, Beijing (CN); Tingliang LIU, Beijing (CN); Jun YAN, Beijing (CN); Rong WANG, Beijing (CN); Qiwei WANG, Beijing (CN)

(21) Appl. No.: 19/479,783

(22) PCT Filed: Apr. 16, 2024
(86) PCT No.: PCT/CN2024/088031

§ 371 Date: Oct. 29, 2025

(30) Foreign Application Priority Data
May 26, 2023 (CN) 202310611454.1

(51) Int. Cl. H10K 59/131

(52) U.S. Cl. CPC H10K 59/131

(57) ABSTRACT

The display substrate includes: a base substrate having a display region and a peripheral region surrounding the display region, the peripheral region including a pad region on one side of the display region; first selection units on the base substrate and in the peripheral region, each first selection unit including an input end and output ends; pads in the pad region; adapter lines in the display region, one end of each adapter line being connected to a corresponding pad, and the other end being connected to the input end of a corresponding first selection unit; first data lines in the display region; and data lead-in lines in the display region, one end of each data lead-in line being connected to the output end of the corresponding first selection unit, and the other end being connected to the corresponding first data line.

### TECHNICAL FIELD

The present disclosure relates to the field of display technology, and in particular to a display substrate and a display apparatus.

### BACKGROUND

An active matrix organic light-emitting diode (AMOLED) has the advantages of self-luminescence, wide color gamut, high contrast, flexibility, high response, flexibility, and the like, and has a wide application prospect. With the rapid development of AMOLED display devices, the demand of customers for products with a medium to large size is more and more prominent, and products such as vehicle-mounted products and NB (network newborn) are blooming everywhere. The application requirements of various products in circular and large-circular shapes are more and more intense.

### SUMMARY OF THE INVENTION

The present disclosure provides a display substrate, including:
a base substrate, wherein the base substrate includes a display region and a peripheral region surrounding the display region, and the peripheral region includes a pad region on one side of the display region;
a plurality of first selection units in the peripheral region; wherein each first selection unit includes an input end and a plurality of output ends, and is configured to electrically connect the plurality of output ends with the input end at different times in a time-sharing manner, respectively;
a plurality of pads in the pad region;
a plurality of adapter lines in the display region, wherein one end of each adapter line is connected to the corresponding pad, and the other end of each adapter line is connected to the input end of the corresponding first selection unit;
a plurality of first data lines in the display region; and
a plurality of data lead-in lines in the display region, wherein one end of each data lead-in line is connected to the output end of the corresponding first selection unit, and the other end of each data lead-in line is connected to the corresponding first data line.

In some embodiments, each adapter line includes: a first adapter portion and a second adapter portion, one end of the first adapter portion is connected to the corresponding pad, the other end of the first adapter portion is connected to one end of the second adapter portion, and the other end of the second adapter portion is connected to the input end of the corresponding first selection unit; and
wherein at least one second adapter portion and at least one data lead-in line are arranged in the same layer, and at least one first adapter portion and at least one first data line are arranged in the same layer.

In some embodiments, first adapter portions of the plurality of adapter lines and the plurality of first data lines are arranged in the same layer; or
first adapter portions of one part of the plurality of adapter lines and the plurality of first data lines are arranged in the same layer, and first adapter portions of the other part of the plurality of adapter lines are arranged in a different layer from both the plurality of first data lines and the plurality of data lead-in lines.

In some embodiments, second adapter portions of the plurality of adapter lines and the plurality of data lead-in lines are arranged in the same layer; or
second adapter portions of one part of the plurality of adapter lines and the plurality of data lead-in lines are arranged in the same layer, and second adapter portions of the other part of the plurality of adapter lines are arranged in a different layer from both the plurality of data lead-in lines and the plurality of first data lines.

In some embodiments, the display substrate further includes: a gate line, wherein an extending direction of the gate line and an extending direction of the second adapter portion are the same; and
wherein the extending direction of the second adapter portion and an extending direction of the first adapter portion are different, and the extending direction of the first adapter portion and an extending direction of each first data line are the same.

In some embodiments, an edge of the display region and a reference axis define a first region and a second region, and the reference axis is a virtual axis passing through the display region along an extending direction of each first data line; and
wherein each of the first region and the second region is provided with multiple of the plurality of first data lines, multiple first selection units connected to the multiple first data lines in the first region are adjacent to the edge of the first region, and multiple first selection units connected to the multiple first data lines in the second region are adjacent to an edge of the second region.

In some embodiments, in the first region and the second region, the plurality of pads connected to the plurality of first data lines arranged from the edge of the display region to a center of the display region are arranged from a center of the pad region to an edge of the pad region; or
the plurality of pads connected to the plurality of first data lines arranged from the center of the display region to the edge of the display region are arranged from the center of the pad region to the edge of the pad region.

In some embodiments, the display substrate further includes: a plurality of second data lines arranged in the display region; and
a plurality of second selection units between the pad region and the display region, wherein each second selection unit includes an input end and a plurality of output ends, the input end of each second selection unit is connected to the corresponding pad, and an output end of each second selection unit are connected to the corresponding second data line.

In some embodiments, an edge of the display region and a reference axis define a first region and a second region, and the reference axis is a virtual axis passing through the display region along an extending direction of each first data line; and
each of the first region and the second region is provided with a second data line.

In some embodiments, each adapter line includes a first adapter portion and a second adapter portion, and at least one first adapter portion is located between any two adjacent second data lines.

In some embodiments, the display region has a circular or elliptical shape.

In some embodiments, a ratio of a width of the pad region to a diameter of the display region is between 1:5 and 1:3.

The present disclosure further provides a display apparatus including the display substrate described in the above embodiments.

### BRIEF DESCRIPTION OF THE DRAWINGS

The accompanying drawings, which are provided for further understanding of the present disclosure and constitute a part of this specification, are for explaining the present disclosure together with the embodiments of the present disclosure, but are not intended to limit the present disclosure. In the drawings:

FIG. 1 is a schematic view of a structure of a display substrate provided in some embodiments.

FIG. 2 is a schematic view of a structure of a display substrate provided in an embodiment of the present disclosure.

FIG. 3 is a schematic view of another structure of a display substrate provided in an embodiment of the present disclosure.

FIG. 4 is a schematic view of a structure of a first selection unit provided in an embodiment of the present disclosure.

FIG. 5 is a schematic view of a structure of an adapter line, a gate line, a first data line, and a data lead-in line provided in an embodiment of the present disclosure.

FIG. 6A is a cross-sectional view taken along a line A-A′ in FIG. 5.

FIG. 6B is another cross-sectional view taken along a line A-A′ in FIG. 5.

FIG. 7 is a cross-sectional view taken along a line B-B′ in FIG. 5.

FIG. 8 is a cross-sectional view taken along a line C-C′ in FIG. 5.

FIG. 9 is a schematic view of another structure of a display substrate provided in an embodiment of the present disclosure.

FIG. 10 is a schematic view of another structure of a display substrate provided in an embodiment of the present disclosure.

### DETAIL DESCRIPTION OF THE EMBODIMENTS

The embodiments of the present disclosure will be described in detail hereinafter with reference to the accompanying drawings. It should be understood that the embodiments described here are only used to illustrate and explain the present disclosure, and should not be construed as limiting the present disclosure.

In this specification, for convenience, the terms “middle”, “upper”, “lower”, “front”, “rear”, “vertical”, “horizontal”, “top”, “bottom”, “inner”, “outer”, and the like indicating an orientation or positional relationship are used to explain a positional relationship of constituent elements with reference to the drawings, which is only for the purpose of describing the specification and simplifying the description, and does not indicate or imply that the device or element referred to must have a specific orientation, be configured and operate in a specific orientation, and thus, should not be construed as limiting the present disclosure. The positional relationship of the constituent elements is changed as appropriate with a direction describing each constituent element. Therefore, the words and phrases described in the specification are not limited thereto, and may be replaced as appropriate depending on the case.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Similarly, the term “comprising”, “including”, or the like means that the element or item preceding the term contains the element or item listed after the term and its equivalent, but does not exclude other elements or items. The term “mounted”, “connected”, “coupled”, or the like is to be construed broadly, for example, may mean fixedly connected, or detachably connected, or integrally connected, or mechanically connected, either directly or indirectly connected through an intervening component, or two elements being internally interconnected. The specific meaning of the above terms in the present disclosure may be understood in a specific case to one of ordinary skill in the art.

A display apparatus includes a display substrate, a flexible circuit board and a driving circuit board. The display substrate includes a display region and a pad region located on one side of the display region, wherein a plurality of gate lines and a plurality of data lines are arranged in the display region, and cross each other to define a plurality of pixel regions. A plurality of pads are arranged in the pad region, and the data lines are electrically connected to the pads through fan-out lines. One end of the flexible circuit board is bound with and connected to the pads, and the other end of the flexible circuit board is electrically connected to the driving circuit board, so that signals are transmitted from the driving circuit board to the data lines through the pads.

In a conventional display screen, a width of the pad region is approximately equal to a width of the display region. In a display screen with a circular shape or a large rounded corner, the width of the pad region is only ¼ or less of the width of the display region AA in the display screen. In this case, in order to make the display screen with the circular shape or the large rounded corner have a high PPI (pixels per inch) display effect, a multiplexer (MUX) is necessarily used.

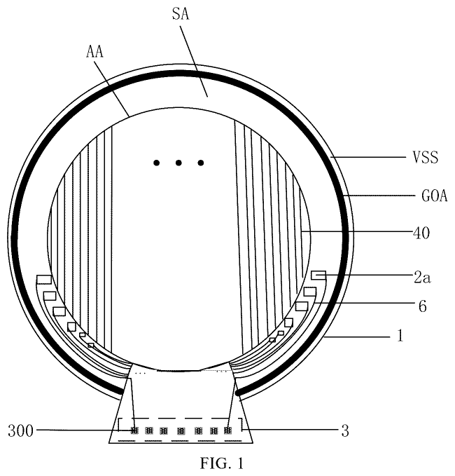

FIG. 1 is a schematic view of a structure of a display substrate provided in some embodiments. As shown in FIG. 1, the display substrate includes: a base substrate 1. The base substrate 1 includes a display region AA and a peripheral region SA surrounding the display region AA, the peripheral region SA including a pad region 3 on one side of the display region AA. A plurality of gate lines (not shown) and a plurality of data lines 40 are arranged on the base substrate 1 and in the display region AA. A plurality of selection units 2a, a plurality of pads 300, a plurality of adapter lines 6, a gate driver on array (GOA), a power line VSS, and the like are provided on the base substrate 1. The power line VSS is used for providing a low level signal to devices in the display substrate. The GOA circuit is used for providing a gate driving signal to the gate lines.

A plurality of pads 300 are arranged in the pad region 3. Each selection unit 2a is embodied as the multiplexer described above and has an input end and a plurality of output ends. One end of each adapter line 6 is connected to the corresponding pad 300, the other end of each adapter line 6 is connected to the input end of the corresponding selection unit 2a, and each output end of the selection unit 2a is connected to an end of one corresponding data line 40.

Each selection unit 2a is used for electrically connecting the input end with different output ends in a time-sharing manner under control of a control signal, so that a signal transmitted on the corresponding adapter line 6 is output to different data lines 4 at different times.

However, when the display substrate is used in a circular display apparatus, since the width of the pad region 3 is only ¼ or less of the width of the circular display region AA, and the number of data lines 40 in the circular display apparatus is large, a large number of adapter lines 6 are required. Therefore, when a large number of selection units 2 and a large number of adapter lines 6 are arranged in the peripheral region SA, a width of the peripheral region SA is large, which impedes the realization of a narrow border of the circular display apparatus.

In addition, as shown in FIG. 1, in the conventional circular display apparatus, the output ends of the selection unit 2 are connected to the end of the data line 40, and thus, a large number of selection units 2 are concentrated at a lower half edge of the display region AA, which is disadvantageous to the placement of the selection units 2.

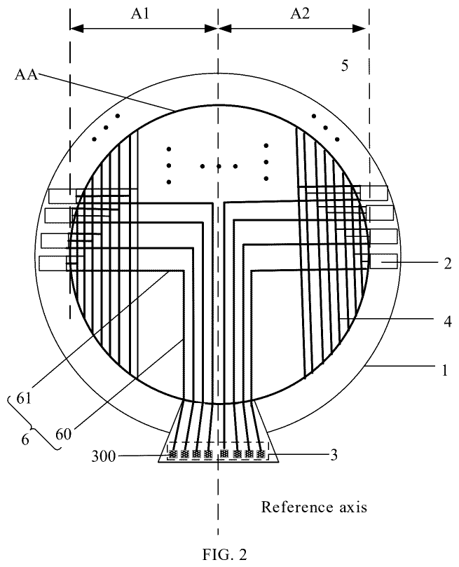

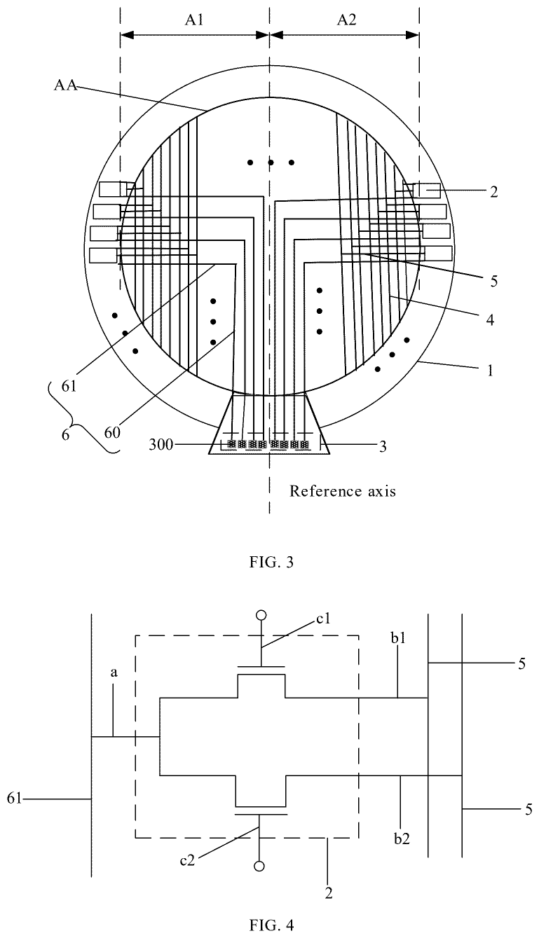

FIG. 2 is a schematic view of a structure of a display substrate provided in an embodiment of the present disclosure, and FIG. 3 is a schematic view of another structure of a display substrate provided in an embodiment of the present disclosure. As shown in FIG. 2 and FIG. 3, the display substrate provided in the present disclosure includes: a base substrate 1, a plurality of first selection units 2, a plurality of pads 3, a plurality of adapter lines 6, a plurality of data lines and a plurality of data lead-in lines 5. The base substrate 1 may be a flexible substrate made of an organic material such as polyimide (PI), or a glass substrate. The base substrate 1 includes a display region AA and a peripheral region SA surrounding the display region AA, the peripheral region SA includes a pad region 3 located on one side of the display region AA, and the plurality of pads 300 are arranged in the pad region 3.

The plurality of first selection units 2 are arranged on the base substrate 1 in the peripheral region SA, and each first selection unit 2 has an input end and a plurality of output ends. Each selection unit 2a is configured to electrically connect the input end with the plurality of output ends at different times in a time-sharing manner.

FIG. 4 is a schematic view of a structure of a first selection unit provided in the embodiment of the present disclosure. As shown in FIG. 4, the first selection unit includes a plurality of thin film transistors. Two thin film transistors are taken as an example in FIG. 4 for description. The two first thin film transistors include a first thin film transistor 100 and a second thin film transistor 101, wherein a source electrode of the first thin film transistor 100 is electrically connected to a source electrode of the second thin film transistor 101 to form an input end a of the first selection unit, which is in turn connected to the adapter line 6. A drain electrode of the first thin film transistor 100 serves as one of the output ends b1, and a drain electrode of the second thin film transistor 101 serves as the other output end b2. Two output ends b1 and b2 are connected to two data lead-in lines 5, respectively. The source electrode and the drain electrode of one of the two thin film transistors may be controlled to be electrically connected to each other by providing a starting signal to the thin film transistor, so that the selective conduction function of the first selection unit is realized.

The plurality of adapter lines 6 are located in the display region AA. One end of each adapter line 6 is connected to a corresponding pad 300, and the other end is connected to the input end of the corresponding first selection unit 2. Since a gap may exist between the pad 300 and the display region AA, the adapter line 6 may be connected to the pad 300 through a first trace located between the pad 300 and the display region AA, and the first trace and the adapter line 6 may be connected to each other to have a one-piece structure. When a gap exists between the input end of the first selection unit 2 and the display region AA, the adapter line 6 may be connected to the input end of the first selection unit 2 through a second trace in the gap, and the second trace and the adapter line 6 may be connected to each other to have a one-piece structure.

The plurality of data lines are located in the display region AA, and include a plurality of first data lines 4. The plurality of data lead-in lines 5 are also located in the display region AA, and one end of each data lead-in line 5 is connected to the output end of the first selection unit 2, and the other end of each data lead-in line 5 is connected to the first data line 4. When there is a gap between the output end of the first selection unit 2 and the display region AA, the data lead-in line 5 may be connected to the output end of the first selection unit 2 through a third trace in the gap. The third trace and the data lead-in line 5 may be connected to each other to have a one-piece structure.

In the embodiment of the present disclosure, the adapter line 6 for connecting the pad 300 to the input end of the first selection unit 2 is arranged in the display region AA, so that the adapter line 6 can be prevented from occupying the space in the peripheral region SA, which is beneficial to realizing a narrow border. The output end of the adapter line 6 is connected to the first data line 4 through the data lead-in line 5 in the display region AA, so that the data lead-in line 5 does not occupy the space in the peripheral region SA. The first selection unit 2 is unnecessarily connected to the end of the first data line 4 by the data lead-in line 5, so that the plurality of first selection units 2 can be dispersedly arranged around the display region AA, and the problem, that there is not enough space for arranging these elements, can be solved.

In some embodiments, as shown in FIGS. 2 and 3, the adapter line 6 includes a first adapter portion 60 and a second adapter portion 61. One end of the first adapter portion 60 is connected to the pad 300, the other end of the first adapter portion 60 is connected to one end of the second adapter portion 61, and the other end of the second adapter portion 61 is connected to the input end of the selection unit 2.

The at least one second adapter portion 61 and the at least one data lead-in line 5 are arranged in the same layer, the at least one first adapter portion 60 and the at least one first data line 4 are arranged in the same layer, and the first adapter portion 60 and the second adapter portion 61 are connected to each other through a first via.

It should be noted that the term “in the same layer” as used herein means that two structures are formed from the same material layer through a patterning process, and therefore, are in the same layer in the layer-to-layer relationship, but which does not mean that a distance between one of the two structures and the base substrate 1 is necessarily the same as a distance between the other one of the two structures and the base substrate 1. Such an arrangement can save cost and simplify the process flow.

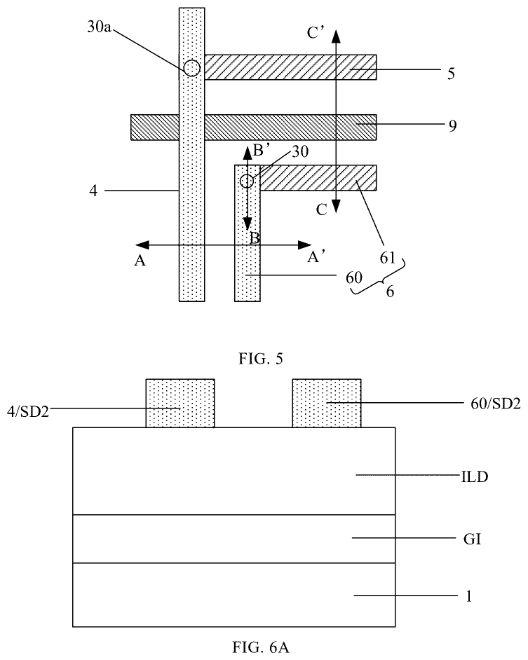

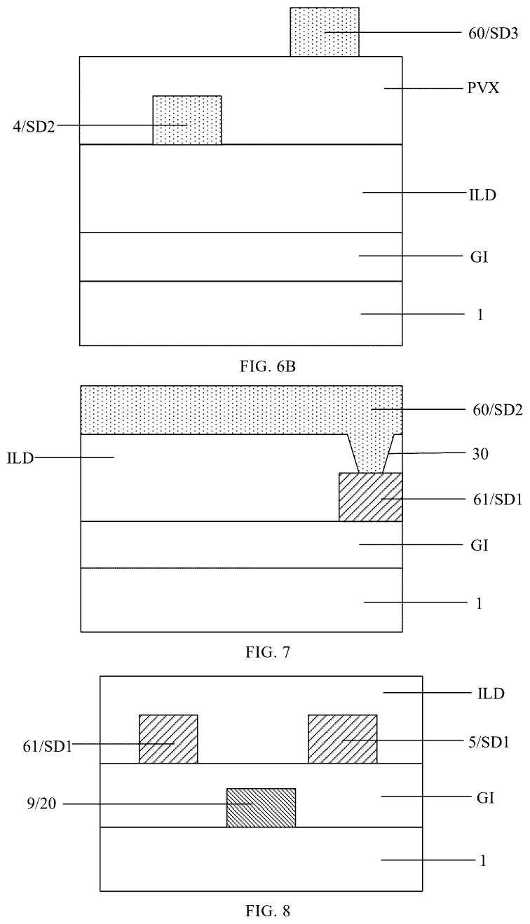

FIG. 5 is a schematic view of a structure of an adapter line, a gate line, a first data line, and a data lead-in line provided in an embodiment of the present disclosure. FIG. 6A is a cross-sectional view taken along a line A-A′ in FIG. 5. FIG. 6B is another cross-sectional view taken along a line A-A′ in FIG. 5. FIG. 7 is a cross-sectional view taken along a line B-B′ in FIG. 5. FIG. 8 is a cross-sectional view taken along a line C-C′ in FIG. 5. As shown in FIGS. 5 to 8, in some embodiments, the display substrate includes: a gate metal layer 20, a gate insulating layer GI, a first metal layer SD1, an interlayer insulating layer ILD, and a second metal layer SD2 sequentially arranged on the base substrate 1.

The plurality of gate lines and the plurality of data lines in the display substrate define a plurality of pixel regions in the display region AA, and each pixel region is provided with a thin film transistor and a light-emitting device. The light-emitting device includes a cathode, an anode, and a luminescent layer therebetween. The gate metal layer 20 includes the plurality of gate lines 9 and gate electrodes of the thin film transistors. The gate electrode layer may be made of gold, an alloy of gold, silver, an alloy of silver, aluminum, an alloy of aluminum, aluminum nitride, tungsten, tungsten nitride, copper, an alloy of copper, nickel, chromium, chromium nitride, molybdenum, an alloy of molybdenum, titanium, titanium nitride, platinum, tantalum, tantalum nitride, neodymium, scandium, strontium ruthenium oxide, zinc oxide, tin oxide, indium oxide, gallium oxide, indium tin oxide, indium zinc oxide, or the like, and the first metal layer SD1 may have a single layer or a plurality of layers.

The gate insulating layer GI is arranged on a side of the gate metal layer 20 away from the base substrate 1, and is made of silicon oxynitride, silicon oxide, silicon nitride, silicon oxycarbide, silicon carbonitride, aluminum oxide, aluminum nitride, tantalum oxide, hafnium oxide, zirconium oxide, or titanium oxide or the like. In addition, the gate insulating layer GI may have a single layer or a plurality of layers.

The first metal layer SD1 is arranged on a side of the gate insulating layer GI away from the base substrate 1. The first metal layer SD1 includes the plurality of second adapter portions 61 and the plurality of data lead-in lines 5, and may be made of, for example, a metal, a metal alloy, a metal nitride, a conductive metal oxide, a transparent conductive material, or the like.

The interlayer insulating layer ILD is arranged on a side of the first metal layer SD1 away from the base substrate 1, and may be made of, for example, a silicon compound, a metal oxide, or the like. In particular, the silicon compounds and the metal oxides listed above may be selected for the interlayer insulating layer ILD, which will not be described in detail here.

The second metal layer SD2 is arranged on a side of the interlayer insulating layer ILD away from the base substrate 1, and includes the plurality of first adapter portions 60, the plurality of first data lines 4, the plurality of second data lines 8, and a plurality of power lines (not shown). The first data lines 4 are connected to the corresponding data lead-in lines 5 through second vias 30a, and the first adapter portions 60 are electrically connected to the corresponding second adapter portions 61 through first vias 30. The second metal layer SD2 may be made of a metal, a metal alloy, a metal nitride, a conductive metal oxide, a transparent conductive material, or the like. The gate electrode layer may be made of gold, an alloy of gold, silver, an alloy of silver, aluminum, an alloy of aluminum, aluminum nitride, tungsten, tungsten nitride, copper, an alloy of copper, nickel, chromium, chromium nitride, molybdenum, an alloy of molybdenum, titanium, titanium nitride, platinum, tantalum, tantalum nitride, neodymium, scandium, strontium ruthenium oxide, zinc oxide, tin oxide, indium oxide, gallium oxide, indium tin oxide, indium zinc oxide, or the like, and the second metal layer SD2 may have a single layer or a plurality of layers.

In the above embodiment, the first adapter portions 60 of the adapter lines 6 are arranged in the same layer as all the first data lines 4. For example, all the first adapter portions 60 and all the first data lines 4 are arranged in the second metal layer SD2. Alternatively, all the first adapter portions 60 and all the first data lines 4 may be arranged in the first metal layer SD1, and all the second adapter portions 61 and all the data lead-in lines 5 may be arranged in the second metal layer SD2.

It should be noted that in other embodiments, the first adapter portions 60 of the adapter lines 6 may alternatively be arranged in layers. For example, the first adapter portions 60 of a part of the adapter lines 6 are arranged in the same layer as all the first data lines 4, and the first adapter portions 60 of another part of the adapter lines 6 are arranged in different layers from the first data lines 4 and the data lead-in lines 5. For example, as shown in FIG. 6B, the display substrate may further include a third metal layer SD3, the first adapter portions 60 of a part of the adapter lines 6 and the first data lines 4 are located in the second metal layer SD2, and the first adapter portions 60 of another part of the adapter lines 6 are located in the third metal layer SD3.

A passivation layer PVX is arranged on a side of the second metal layer SD2 away from the base substrate 1, and a material of the passivation layer PVX may include a silicon compound, such as silicon oxide, silicon nitride or silicon oxynitride. The third metal layer SD3 is arranged on a side of the passivation layer PVX away from the base substrate 1, and may include the adapter lines 6 or the data lead-in lines 5. A material of the third metal layer SD3 may be the same as that of the first metal layer SD1 and/or the second metal layer SD2.

In some embodiments, as shown in FIG. 5, extending directions of the first adapter portion 60 and the first data line 4 are the same, wherein the same direction is not strictly in the sense that the extending directions of the first adapter portion 60 and the first data line 4 are completely parallel to each other. The extending directions of the first adapter portion 60 and the first data line 4 are the same as long as an angle between the extending directions of the first adapter portion 60 and the first data line 4 is between 0° and 10°. Extending directions of the first adapter portion 60 and the second adapter portion 61 are different. For example, an angle between the extending directions of the first adapter portion 60 and the second adapter portion 61 is 90°.

In some embodiments, as shown in FIG. 5, extending directions of the second adapter portion 61 and the gate line 9 are the same.

In some embodiments, the second adapter portions 61 of all the adapter lines 6 are arranged in the same layer as all the data lead-in lines 5. For example, the second adapter portions 61 of all the adapter lines 6 and all the data lead-in lines 5 are located in the second metal layer SD2. Alternatively, all the second adapter portions 61 and all the data lead-in lines 5 may be arranged in the first metal layer SD1, and all the first adapter portions 60 and all the first data lines 4 may be arranged in the second metal layer SD2.

It should be noted that in other embodiments, the second adapter portions 61 of all the adapter lines 6 may be alternatively arranged in layers. For example, the second adapter portions 61 of a part of the adapter lines 6 are arranged in the same layer as all the data lead-in lines 5, and the second adapter portions 61 of another part of the adapter lines 6 are arranged in different layers from the first data lines 4 and the data lead-in lines 5. For example, the display substrate may further include the third metal layer, the second adapter portions 61 of a part of the adapter lines 6 and the data lead-in lines 5 are located in the second metal layer SD2, and the second adapter portions 61 of another part of the adapter lines 6 are located in the third metal layer.

For another example, the second adapter portions 61 of all the adapter lines 6 and a part of the data lead-in lines 5 are arranged in the same layer, and another part of the data lead-in lines 5 are arranged in different layers from the second adapter portions 61, and the first data lines 4. For example, the display substrate may further include the third metal layer, a part of the data lead-in lines 5 and the second adapter portions 61 of the adapter lines 6 are located in the second metal layer SD2, and another part of the data lead-in lines 5 are located in the third metal layer.

In other embodiments, the first data lines 4, the data lead-in lines 5 and the adapter lines 6 may be arranged in layers. For example, all the first data lines 4 are located in the first metal layer SD1, all the adapter lines 6 are located in the second metal layer SD2, and all the data lead-in lines 5 are located in the third metal layer SD3.

In some embodiments, as shown in FIGS. 2 and 3, an edge of the display region AA and a reference axis define a first region and a second region, and the reference axis is a virtual axis passing through the display region AA along an extending direction of the first data line 4. Multiple first data lines 4 are arranged in each of the first region A1 and the second region A2, multiple first selection units 2 connected to the multiple first data lines 4 in the first region A1 are adjacent to an edge of the first region A1, and multiple first selection units 2 connected to the multiple first data lines 4 in the second region A2 are adjacent to an edge of the second region A2. Here, the term “adjacent to an edge” means that a distance between the first selection unit 2 and the edge of the second region A2 is less than ½, or ⅓, or ¼ of a width of the first selection unit 2. For example, the first selection unit 2 is in contact with the edge of the second region A2.

In some embodiments, as shown in FIGS. 2 and 3, the number of the first data lines 4 in the first region A1 and the number of the first data lines 4 in the second region A2 is the same or approximately the same, where the “approximately the same” means that a ratio of the number of the first data lines 4 in the first region A1 and the number of the first data lines 4 in the second region A2 is between 1:1.2 and 1.2:1. This arrangement is advantageous for display uniformity of the display screen.

In some embodiments, as shown in FIGS. 2 and 3, in the first region A1, a distance between every two adjacent first adapter portions 60 may be constant, and a distance between every two adjacent second adaptor portions 61 may be constant. Also, in the second region A2, a distance between every adjacent two first adapter portions 60 may be constant, and a distance between every two adjacent second adaptor portions 61 may be constant.

In some embodiments, as shown in FIG. 2, in the first region A1 and the second region A2, the plurality of pads 300 connected to the plurality of first data lines 4 arranged from the edge of the display region AA to a center of the display region AA are arranged from an edge of the pad region 3 to a center of the pad region 3. That is, the pad 300 connected to the first data line 4 closer to the edge of the display region AA is closer to the edge of the pad region 3, and the pad 300 connected to the first data line 4 closer to the center of the display region AA is closer to the center of the pad region 3.

At this time, all the first selection units 2 may be uniformly distributed in the peripheral region SA adjacent to an upper half portion of the display region AA. It should be noted that the “upper half portion” of the display region AA means a region extending from one end of the display region AA away from the pad region 3 to one end of the display region AA close to the pad region 3 and occupying ⅓ to ⅔ of a total area of the display region AA. In this way, the adapter lines 6 are arranged inside the display region AA, and the first selection units 2 are uniformly arranged in the peripheral region SA adjacent to the upper half portion of the display region AA, so that not only the occupied area in the peripheral region of the display substrate can be reduced, but also the problem in the embodiment in FIG. 1, that there is no enough space for arranging the first selection units 2 and the large number of adapter lines 6, can be solved.

In other embodiments, as shown in FIG. 3, in the first region Al and the second region A2, the plurality of pads 300 connected to the plurality of first data lines 4 arranged from the edge of the display region AA to the center of the display region AA are arranged from the center of the pad region 3 to the edge of the pad region 3. That is, the pad 300 connected to the first data line 4 closer to the edge of the display region AA is closer to the center of the pad region 3, and the pad 300 connected to the first data line 4 closer to the center of the display region AA is closer to the edge of the pad region 3.

At this time, all the first selection units 2 may be uniformly distributed in the peripheral region SA adjacent to a lower half portion of the display region AA. It should be noted that the “lower half portion” of the display region AA means a region extending from one end of the display region AA close to the pad region 3 to one end of the display region AA away from the pad region 3 and occupying ⅓ to ⅔ of a total area of the display region AA. In this way, the adapter lines 6 are arranged inside the display region AA, and the first selection units 2 are uniformly arranged in the peripheral region SA adjacent to the lower half portion of the display region AA, so that not only the occupied area in the peripheral region of the display substrate can be reduced, but also the problem in the embodiment in FIG. 1, that there is no enough space for arranging the first selection units 2 and the large number of adapter lines 6, can be solved.

In the embodiments shown in FIGS. 2 and 3, all the data lines on the display substrate may be used as the first data lines 4.

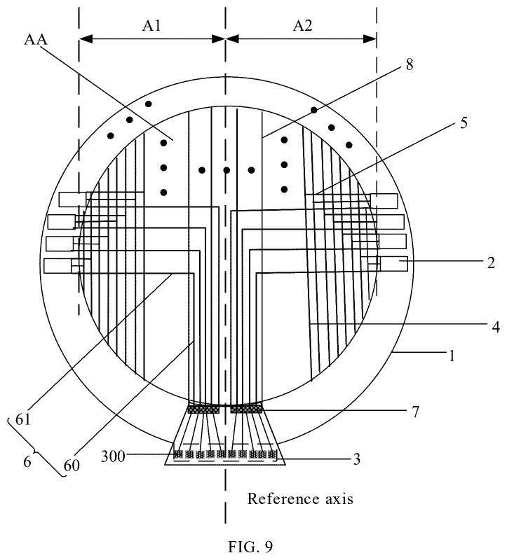

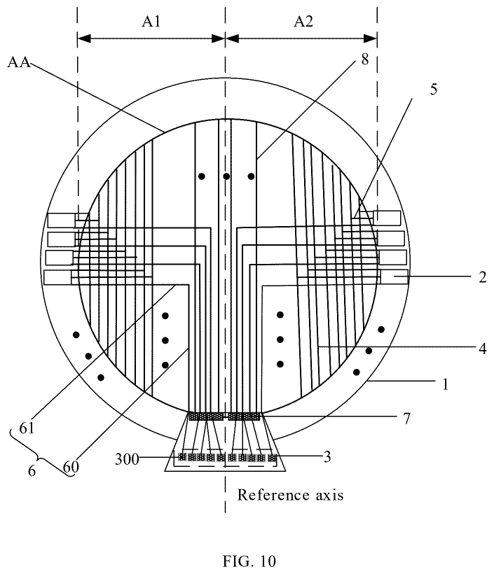

FIG. 9 is a schematic view of another structure of a display substrate provided in the embodiment of the present disclosure. FIG. 10 is a schematic view of another structure of a display substrate provided in the embodiment of the present disclosure. As shown in FIG. 9 and FIG. 10, the plurality of data lines in the display substrate include all second data lines 8 in addition to all the first data lines 4. In some embodiments, all the first data lines 4 and all the second data lines 8 are arranged in the same layer and have the same extending direction, or a part of the first data lines 4 and the second data lines 8 are arranged in the same layer and have the same extending direction.

In addition, the display substrate further includes a plurality of second selection units 7. The plurality of second selection units 7 are arranged between the pad region 3 and the display region, and each second selection unit 7 includes an input end and a plurality of output ends, the input end of the second selection unit 7 is connected to the corresponding pad 300 in the pad region 3, and each output end of the second selection unit 7 is connected to the corresponding second data line 8. The second selection unit 7 is configured to make the plurality of output ends be electrically connected to the input end at different times in a time-sharing manner. The specific structure of the second selection unit 7 may refer to the structure of the first selection unit 2 described above, and is not described herein again.

As shown in FIG. 9, the plurality of second selection units 7 are arranged between the pad region 3 and the display region AA, input ends of the plurality of second selection units 7 are connected to the plurality of pads 300 in the pad region 3, and output ends of the plurality of second selection units 7 are connected to the plurality of second data lines 8. Herein, compared with the first data line 7, the second data line 8 does not need the adapter line 6 and the data lead-in line 5, but is connected to the pad 300 through the second selection unit 7, so that the number of the adapter lines 6 and the number of the data lead-in lines 5 in the display region AA can be reduced.

In addition, as shown in FIG. 9, the plurality of first selection units 2 are uniformly arranged in the upper half portion of the display region AA away from the pad region 3. In this arrangement, like in the embodiment shown in FIG. 2, in the first region Al and the second region A2, the plurality of pads 300 connected to the plurality of first data lines 4 arranged from the edge of the display region AA to the center of the display region AA are arranged from the edge of the pad region 3 to the center of the pad region 3. This arrangement is combined with the arrangement of the second data lines 8, so that the first selection units 2 are uniformly arranged on the upper half portion of the display region AA, the second selection units 7 are uniformly arranged between the pad region 3 and the display region AA, and one end of each second data line 8 is connected to the corresponding second selection unit 7 without the adapter lines. In addition, with the adapter lines, each first data line 4 may be connected to the corresponding first selection unit 2 arranged on the upper half portion of the display region AA through the corresponding data lead-in line 5, and then is connected to the pad 300 in the pad region 3 through the corresponding first selection unit 2 and the corresponding adapter line 6. Compared with the routing manner of the display substrate in the embodiments of FIGS. 2 and 3, by combining with the connection manners of the first data lines 4 and the second data lines 8, the routing manner of the display substrate in the embodiment of FIG. 9 not only saves an occupied area of the traces in the peripheral region SA, but also saves an occupied area of the traces in the display region AA.

In addition, compared with the routing manner of the display substrate in the embodiments of FIG. 2 and FIG. 3, in the embodiment of the present disclosure, the number of the adapter lines 6 in the display region AA in the display substrate is reduced, so that the density of the traces in the display region AA is further reduced, which is beneficial to improving the flatness of the anode of the light-emitting device in the display substrate and the transmittance of the display substrate.

As shown in FIG. 10, the plurality of second selection units 7 are arranged between the pad region 3 and the display region AA, input ends of the plurality of second selection units 7 are connected to the plurality of pads 300 in the pad region 3, and output ends of the plurality of second selection units 7 are connected to the plurality of second data lines 8. Here, compared with the first data line 7, the second data line 8 does not need the adapter lines 6 and the data lead-in lines 5, but is connected to the pad 300 through the second selection unit 7, so that the number of the adapter lines 6 and the number of the data lead-in lines 5 in the display region AA can be reduced.

In addition, as shown in FIG. 10, the plurality of first selection units 2 are uniformly arranged in the lower half portion of the display region AA close to the pad region 3. In this arrangement, like in the embodiment shown in FIG. 3, in the first region A1 and the second region A2, the plurality of pads 300 connected to the plurality of first data lines 4 arranged from the center of the display region AA to the edge of the display region AA are arranged from the edge of the pad region 3 to the center of the pad region 3. This arrangement is combined with the arrangement of the second data lines 8, so that the first selection units 2 are uniformly arranged on the lower half portion of the display region AA, the second selection units 7 are uniformly arranged between the pad region 3 and the display region AA, and one end of each second data line 8 is connected to the corresponding second selection unit 7 without the adapter lines. In addition, with the adapter lines, each first data line 4 may be connected to the corresponding first selection unit 2 arranged on the lower half portion of the display region AA through the corresponding data lead-in line 5, and then is connected to the pad 300 in the pad region 3 through the corresponding first selection unit 2 and the corresponding adapter line 6. Compared with the routing manner of the display substrate in the embodiments of FIGS. 2 and 3, by combining with the connection manners of the first data lines 4 and the second data lines 8, the routing manner of the display substrate in the embodiment of FIG. 10 not only saves an occupied area of the traces in the peripheral region SA, but also saves an occupied area of the traces in the display region AA.

Similar to FIG. 9, the embodiment shown in FIG. 10 can reduce the density of the traces in the display region AA, which is beneficial to improving the flatness of the anode of the light-emitting device in the display substrate and the transmittance of the display substrate.

In the embodiment shown in FIGS. 9 and 10, the second data lines 8 are provided in each of the first region A1 and the second region A2. When the number of the second data lines 8 in the display region AA is small, the plurality of second data lines 8 may be arranged in the first region A1 and the second region A2, respectively, the second data lines 8 in the first region A1 and the second region A2 may be arranged at positions close to the center of the pad region 3, or at positions close to both ends of the pad region 3, respectively.

In some embodiments, the adapter line 6 includes the first adapter portion 60 and the second adapter portion 61, and at least one first adapter portion 60 is arranged between any two adjacent second data lines 8.

In some embodiments, a shape of the display region AA is a circle, an ellipse, a shape with large rounded corners, or the like, which is set according to the user's needs and is not limited herein.

In some embodiments, a ratio of a width of the pad region 3 to a diameter of the display region AA is between 1:5 and 1:3, for example, 1:5, 1:4, or 1:3. The width of the pad region 3 refers to a size of the pad region 3 in a first direction perpendicular to a direction from the display region AA to the pad region 3.

In some embodiments, the display substrate may further include: a planarization layer, and a pixel definition layer (not shown). The planarization layer is arranged on a side of the second metal layer away from the base substrate. The planarization layer may be made of an organic insulating material, for example, including a resin material such as polyimide, epoxy, acryl, polyester, photoresist, polyacrylate, polyamide, or siloxane.

The pixel definition layer is arranged on a side of the planarization layer away from the base substrate, and is provided with a plurality of openings therein. The light-emitting devices are in one-to-one correspondence with the openings, a luminescent layer of each light-emitting device is arranged in the corresponding opening, and the light-emitting device includes: a first electrode, a second electrode, and a luminescent layer between the first electrode and the second electrode. For example, the first electrode is an anode and the second electrode is a cathode. Optionally, the first electrode is a reflective electrode made of a metal material, and the second electrode is a transparent electrode made of a transparent conductive material (e.g., indium tin oxide). The luminescent layer may include, stacked in order: a hole injection layer, a hole transport layer, an electron transport layer, and an electron injection layer. The first electrode is located between the pixel definition layer and the planarization layer, a portion of the first electrode is exposed by the opening, and the second electrodes of the plurality of light-emitting devices may have a one-piece structure.

Alternatively, in some embodiments, the display substrate may further include: an encapsulation layer on a side of the light-emitting device away from the base substrate and a protective layer on a side of the encapsulation layer away from the base substrate. The protective layer may be a glass cover plate or a cover plate made of other materials, and an orthographic projection of the protective layer on the base substrate may cover the whole base substrate. The encapsulation layer may include a first inorganic encapsulation layer, a second inorganic encapsulation layer, and an organic encapsulation layer therebetween, and the encapsulation layer is used to cover and encapsulate the plurality of light-emitting devices to prevent moisture and/or oxygen in the external environment from corroding the light-emitting devices.

In some embodiments, a bending region is arranged between the plurality of pads 300 and the display region AA, and the base substrate 1 may be bent along the bending region, so that the pad region 3 where the plurality of pads 300 are located is bent to a non-display side of the display region AA.

The present disclosure further provides a display apparatus including the display substrate in the above embodiments. The display apparatus may be any product or component with a display function, such as an OLED panel, a QLED display panel, a mobile phone, a tablet computer, a television, a display, a notebook computer, a digital photo frame, a navigator and the like.

It should be understood that, the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A display substrate, comprising:
a base substrate, wherein the base substrate comprises a display region and a peripheral region surrounding the display region, and the peripheral region comprises a pad region on one side of the display region;
a plurality of first selection units in the peripheral region; wherein each first selection unit of the plurality of first selection units comprises an input end and a plurality of output ends, and is configured to electrically connect the plurality of output ends with the input end at different times in a time-sharing manner, respectively;
a plurality of pads in the pad region;
a plurality of adapter lines in the display region, wherein one end of each adapter line of the plurality of adapter lines is connected to a corresponding pad of the plurality of pads, and the other end of the adapter line is connected to the input end of a corresponding first selection unit of the plurality of first selection units;
a plurality of first data lines in the display region; and
a plurality of data lead-in lines in the display region, wherein one end of each data lead-in line of the plurality of data lead-in lines is connected to the output end of a corresponding first selection unit of the plurality of first selection units, and the other end of the data lead-in line is connected to a corresponding first data line of the plurality of first data lines.

2. The display substrate of claim 1, wherein each adapter line comprises: a first adapter portion and a second adapter portion, one end of the first adapter portion is connected to the corresponding pad, the other end of the first adapter portion is connected to one end of the second adapter portion, and the other end of the second adapter portion is connected to the input end of the corresponding first selection unit; and
wherein at least one second adapter portion and at least one data lead-in line are arranged in a same layer, and at least one first adapter portion and at least one first data line are arranged in a same layer.

3. The display substrate of claim 2, wherein first adapter portions of the plurality of adapter lines and the plurality of first data lines are arranged in a same layer; or
first adapter portions of one part of the plurality of adapter lines and the plurality of first data lines are arranged in a same layer, and first adapter portions of the other part of the plurality of adapter lines are arranged in a different layer from both the plurality of first data lines and the plurality of data lead-in lines.

4. The display substrate of claim 2, wherein second adapter portions of the plurality of adapter lines and the plurality of data lead-in lines are arranged in a same layer; or
second adapter portions of one part of the plurality of adapter lines and the plurality of data lead-in lines are arranged in a same layer, and second adapter portions of the other part of the plurality of adapter lines are arranged in a different layer from both the plurality of data lead-in lines and the plurality of first data lines.

5. The display substrate of claim 2, further comprising: a plurality of gate lines, wherein the plurality of gate lines has a same extending direction as the second adapter portion; and
wherein the second adapter portion has a different extending direction from the first adapter portion, and the first adapter portion has a same extending direction as the plurality of first data lines.

6. The display substrate of claim 2, wherein an edge of the display region and a reference axis define a first region and a second region, and the reference axis is a virtual axis passing through the display region along an extending direction of the plurality of first data lines; and
wherein each of the first region and the second region is provided with multiple first data lines of the plurality of first data lines, multiple first selection units connected to the multiple first data lines in the first region are adjacent to an edge of the first region, and multiple first selection units connected to the multiple first data lines in the second region are adjacent to an edge of the second region.

7. The display substrate of claim 6, wherein in the first region and the second region, the plurality of pads connected to the plurality of first data lines arranged from the edge of the display region to a center of the display region are arranged from a center of the pad region to an edge of the pad region; or
the plurality of pads connected to the plurality of first data lines arranged from a center of the display region to the edge of the display region are arranged from a center of the pad region to an edge of the pad region.

8. The display substrate of claim 1, further comprising:
a plurality of second data lines arranged in the display region; and
a plurality of second selection units between the pad region and the display region, wherein each second selection unit of the plurality of second selection units comprises an input end and a plurality of output ends, the input end of the second selection unit is connected to a corresponding pad of the plurality of pads, and each output end of the plurality of output ends of the second selection unit is connected to a corresponding second data line of the plurality of second data lines.

9. The display substrate of claim 8, wherein an edge of the display region and a reference axis define a first region and a second region, and the reference axis is a virtual axis passing through the display region along an extending direction of the plurality of first data lines; and
each of the first region and the second region is provided with at least one second data line of the plurality of second data lines.

10. The display substrate of claim 8, wherein each adapter line of the plurality of adapter lines comprises a first adapter portion and a second adapter portion, and at least one first adapter portion is arranged between any two adjacent second data lines of the plurality of second data lines.

11. The display substrate of claim 1, wherein the display region has a circular or elliptical shape.

12. The display substrate of claim 11, wherein a ratio of a width of the pad region to a diameter of the display region is between 1:5 and 1:3.

13. A display apparatus, comprising the display substrate of claim 1.

14. The display substrate of claim 2, further comprising:
a plurality of second data lines arranged in the display region; and
a plurality of second selection units between the pad region and the display region, wherein each second selection unit of the plurality of second selection units comprises an input end and a plurality of output ends, the input end of the second selection unit is connected to a corresponding pad of the plurality of pads, and each output end of the plurality of output ends of the second selection unit is connected to a corresponding second data line of the plurality of second data lines.

15. The display substrate of claim 3, further comprising:
a plurality of second data lines arranged in the display region; and
a plurality of second selection units between the pad region and the display region, wherein each second selection unit of the plurality of second selection units comprises an input end and a plurality of output ends, the input end of the second selection unit is connected to a corresponding pad of the plurality of pads, and each output end of the plurality of output ends of the second selection unit is connected to a corresponding second data line of the plurality of second data lines.

16. The display substrate of claim 4, further comprising:
a plurality of second data lines arranged in the display region; and
a plurality of second selection units between the pad region and the display region, wherein each second selection unit of the plurality of second selection units comprises an input end and a plurality of output ends, the input end of the second selection unit is connected to a corresponding pad of the plurality of pads, and each output end of the plurality of output ends of the second selection unit is connected to a corresponding second data line of the plurality of second data lines.

17. The display substrate of claim 5, further comprising:
a plurality of second data lines arranged in the display region; and
a plurality of second selection units between the pad region and the display region, wherein each second selection unit of the plurality of second selection units comprises an input end and a plurality of output ends, the input end of the second selection unit is connected to a corresponding pad of the plurality of pads, and each output end of the plurality of output ends of the second selection unit is connected to a corresponding second data line of the plurality of second data lines.

18. The display substrate of claim 6, further comprising:
a plurality of second data lines arranged in the display region; and
a plurality of second selection units between the pad region and the display region, wherein each second selection unit of the plurality of second selection units comprises an input end and a plurality of output ends, the input end of the second selection unit is connected to a corresponding pad of the plurality of pads, and each output end of the plurality of output ends of the second selection unit is connected to a corresponding second data line of the plurality of second data lines.

19. The display substrate of claim 7, further comprising:
a plurality of second data lines arranged in the display region; and
a plurality of second selection units between the pad region and the display region, wherein each second selection unit of the plurality of second selection units comprises an input end and a plurality of output ends, the input end of the second selection unit is connected to a corresponding pad of the plurality of pads, and each output end of the plurality of output ends of the second selection unit is connected to a corresponding second data line of the plurality of second data lines.

20. The display substrate of claim 19, wherein an edge of the display region and a reference axis define a first region and a second region, and the reference axis is a virtual axis passing through the display region along an extending direction of the plurality of first data lines; and
each of the first region and the second region is provided with at least one second data line of the plurality of second data lines.
